(19) United States
(12) Patent Application Publication
(10) Pub. No.: US 2026/0247536 A1
(43) Pub. Date: Aug. 20, 2026

(54) ELECTRICAL CONTROL UNIT, MANUFACTURING METHOD FOR PRODUCING AN ELECTRICAL CONTROL UNIT, AND A FORMING TOOL FOR PRODUCING A CONTROL UNIT

(71) Applicant: HELLA GmbH & Co. KGaA, Lippstadt (DE)

(72) Inventors: Bastian BLOEMEKE, Diemelstadt (DE); Marvin Marcel KRZIKALLA, Rheda-Wiedenbrueck (DE); Sven KULLICK, Lippstadt (DE); Sebastian MAEHLING, Erwitte (DE); Thomas WIESE, Lippstadt (DE); Christoffer ZEHNDER, Lippstadt (DE)

(73) Assignee: HELLA GmbH & Co. KGaA, Lippstadt (DE)

(21) Appl. No.: 19/543,323

(22) Filed: Feb. 18, 2026

(30) Foreign Application Priority Data
Feb. 18, 2025 (DE) 10 2025 106 020.7

(51) Int. Cl. H05K 1/181; H05K 1/11; H05K 13/00; H05K 13/04

(52) U.S. Cl. CPC H05K 1/181; H05K 1/115; H05K 13/0069; H05K 13/0465; H05K 2201/10166; H05K 2201/10189; H05K 2201/10272

(57) ABSTRACT

An electrical control unit having a circuit board, a component arranged on a first side of the circuit board, and a busbar which bears against a second side of the circuit board. A contact protrusion of the busbar extends into a through-hole of the circuit board such that an end face of the contact protrusion is arranged flush with the first side of the circuit board in a longitudinal direction of the contact protrusion, The contact protrusion in an original state has a predefined maximum length and is mechanically formed to an end-assembly length in the end-assembled state.

This nonprovisional application claims priority under 35 U.S.C. § 119(a) to German Patent Application No. 10 2025 106 020.7, which was filed in Germany on February 18, 2025, and which is herein incorporated by reference.

### BACKGROUND OF THE INVENTION

### Field of the Invention

The invention relates to an electrical control unit having a circuit board, a component which is arranged on a first side of the circuit board, and a busbar which is arranged on a second side of the circuit board, wherein the busbar has a contact protrusion and the circuit board has a through-hole corresponding to the contact protrusion, wherein the contact protrusion extends into a through-hole of the circuit board such that an end face of the contact protrusion is arranged flush with the first side of the circuit board in the longitudinal direction of the contact protrusion and is electrically contacted with the component.

### Description of the Background Art

Such electrical control units are known from the prior art, wherein the electrical control units typically have a circuit board, a plurality of components arranged on the circuit board and electrically contacted with the circuit board, and at least one busbar electrically contacted with the component and/or with the circuit board. The busbar can be mechanically and electrically connected to the circuit board and to the component in such a way that the busbar has at least one contact protrusion which engages in a through-hole of the circuit board, wherein the contact protrusion is connected to the circuit board by a connection to the component which is additionally connected to the circuit board. The connection of the component to the circuit board and to the contact protrusion is made on the circuit board on a common first side facing away from the busbar. In this case, with the side facing the circuit board, the component is electrically and mechanically connected to the end face of the contact protrusion and to the circuit board, in particular to an electrical conductor layer. To create such a connection, the end face of the contact protrusion and the first side of the circuit board must be flush with each other. Such an electrical control unit is disclosed, for example, in EP 2 043 412 A1.

The problem here is that, on the one hand, the circuit boards can be designed basically with different thicknesses, and, on the other hand, there may be manufacturing tolerances for the busbar and the circuit board, so that the flushness between the end face of the contact protrusion and the first side of the circuit board is not always ensured. To achieve flushness, the circuit board and the busbar are accordingly usually positioned relative to each other, which creates an undesirable gap between the second side of the circuit board and the busbar. Such a gap, in turn, makes it difficult to populate the circuit board with components, wherein when the component is soldered, the solder can flow uncontrollably into the gap. Furthermore, there may be an additional gap between the circumferential surface of the contact protrusion and the circumferential surface of the through-hole, which poses a risk of insufficient contact between the contact protrusion and the component, because the solder could flow uncontrollably into the gap and thus out of the contacting area between the contact protrusion and the component.

### SUMMARY OF THE INVENTION

It is therefore an object of the invention to provide an electrical control unit in which the busbar can be easily and reliably attached to the circuit board and electrically connected to a component and/or to the circuit board.

According to an example of the invention, the contact protrusion in an original state has a predefined maximum length and is mechanically formed to an end-assembly length in the end-assembled state.

Therefore, the contact protrusion of the busbar can be adapted to the thickness of the circuit board as required, i.e., to be circuit-board-specific, during assembly of the busbar, whereby such a length of the contact protrusion is realized in a circuit-board-specific manner by mechanical forming, in particular by upsetting. Due to the adapted length of the contact protrusion, the busbar is in contact with the second side of the circuit board and the end face of the contact protrusion is flush with the first side of the circuit board.

Therefore, the busbar can be connected to the circuit board in a simple and reliable manner, in particular mechanically and electrically, whereby an unwanted gap between the second side of the circuit board and the busbar can be avoided and nevertheless the end face of the contact protrusion can be arranged flush with the first side of the circuit board. In particular, this can make it possible for the busbars to be manufactured independently of the characteristics of the circuit board and nevertheless to be attached to circuit boards of different thicknesses, whereby the contact protrusion is adapted to the corresponding circuit board during assembly of the electrical control unit, i.e., in a circuit-board-specific manner, by mechanical forming of the contact protrusion, in particular by upsetting of the contact protrusion.

Preferably, the contact protrusion is upset such that the end-assembly outer diameter of the contact protrusion is, at least in sections, greater than the original outer diameter, wherein the contact protrusion in the original state is spaced apart, at least in sections, from an inner circumferential surface when viewed in the circumferential direction, and in the end-assembled state is supported transversely to the longitudinal direction of the contact protrusion on the circuit board via the inner circumferential surface of the through-hole. During upsetting of the contact protrusion, the contact protrusion is shortened, as a result of which the material of the contact protrusion is pressed radially outward, thereby increasing the diameter of the contact protrusion. In particular, the upsetting of the contact protrusion causes a curved or bulging circumferential surface of the contact protrusion, such that the end-assembly outer diameter of the contact protrusion is greatest in the center in the longitudinal direction and decreases from the center toward the edge. In this case, the contact protrusion, when viewed in the longitudinal direction, is in contact circumferentially with the inner circumferential surface of the through-hole in the central area. Alternatively, the contact protrusion can be bulged over its entire or nearly its entire length, as a result of which the contact protrusion again has a substantially cylindrical longitudinal section and thereby bears against the circumferential surface of the through-hole over the entire circumferential surface. As a result, the busbar is positioned or mounted on the circuit board also transversely to the longitudinal direction. Additionally, a force-fitting connection can be present between the contact protrusion and the inner circumferential surface of the through-hole in the longitudinal direction of the contact protrusion, as a result of which the contact protrusion and the circuit board are positioned and held relative to each other for a joining process between the component and the contact protrusion as well as the circuit board.

The contact protrusion can have a U-shaped longitudinal section. In other words, the contact protrusion can be configured as being hollow. During mechanical forming, i.e., during forming, the side walls of the contact protrusion are subjected to pressure, whereby starting at a certain load in the longitudinal direction of the contact protrusion the side walls of the hollow contact protrusion bulge radially outward, as a result of which the outer diameter of the contact protrusion increases. Because the contact protrusion is configured as hollow or with a U-shaped longitudinal section, a relatively low force or load is required for mechanically forming the contact protrusion. The end face of the contact protrusion is preferably circular. In a preferred embodiment, the contact protrusion has a constant wall thickness. In particular, the busbar is designed as a sheet metal part. To manufacture the busbar, the busbar is punched out of a sheet metal blank and the contact protrusion is produced by mechanical forming, in particular by deep drawing. As a result, the busbar with a hollow contact protrusion can be manufactured simply and cost-effectively.

The contact protrusion can also be made as a solid material. Preferably, the busbar has a forming-tool engagement recess on a side facing away from the contact protrusion. The forming-tool engagement recess is arranged in alignment with the contact protrusion and serves to ensure that only the contact protrusion is mechanically formed during the forming process, and that mechanical forming of other areas of the busbar is avoided as much as possible. In this case, a component of the forming tool engages in the forming-tool engagement recess, wherein the component provides a counterforce to a load causing the mechanical deformation of the contact protrusion. The forming-tool engagement recess also serves to optimize the shaping of the contact protrusion in the flow-pressing process.

The busbar can have a plurality of contact protrusions such that different components can be electrically connected to each other via the busbar. Each contact protrusion in each case extends into a through-hole of the circuit board, so that the circuit board has a plurality of through-holes. In a preferred embodiment, a plurality of busbars are arranged on the second side, wherein the busbars have at least one contact protrusion. As a result, different electrical connections can be realized by the different busbars. Advantageously, the busbar is equipped with a plug-in tab for a plug connection for connecting a cable for the input or output of current. Alternatively, the busbar can also be provided with a threaded stub, a crimp connection, a threaded hole, or a weld geometry for connecting a cable or busbar for the input or output of current. In both cases, reliable contacting and simple manufacturing are ensured.

The component can be a power semiconductor component or an electrical connecting element, for example a busbar. Advantageously, the power semiconductor component can be designed as an SMD component. This allows the control unit to be manufactured in a particularly compact form. For example, by means of an electrical connecting element, two contact protrusions of different busbars can be connected to one another on the first side of the circuit board.

The object is also achieved by a manufacturing process for an electrical control unit or for producing an electrical control unit, as well as by a forming tool for producing the electrical control unit.

In the manufacturing process, a circuit board, a component, and a busbar are first provided. The busbar is then mounted on the circuit board, wherein the contact protrusion is inserted into the through-hole of the circuit board and mechanically formed from the maximum length to the predefined length, such that the end face of the contact protrusion is arranged flush with the first side of the circuit board and the busbar bears against the second side of the circuit board. Finally, the component is electrically and mechanically connected, in particular soldered, at least to the contact protrusion, preferably to the contact protrusion and the circuit board.

The forming tool comprises a receiving unit which is designed to receive a busbar and a circuit board, wherein during the forming process the busbar bears against the receiving unit and the circuit board bears with a second side against the busbar, such that a contact protrusion of the busbar is arranged in a through-hole of the circuit board; it also comprises a hold-down device which bears against a first side of the circuit board during the forming process, and a punch, which is translationally movable such that during the forming process the punch acts on the end face of the contact protrusion. During the forming process, the circuit board and the busbar are positioned on the receiving unit in such a way that the busbar bears against the second side of the circuit board and the contact protrusion extends beyond the first side of the circuit board in the longitudinal direction of the contact protrusion. The hold-down device is then attached to the circuit board, for example, by a translational movement, whereby the busbar and the circuit board are pressed together and are thereby held together in the longitudinal direction of the contact protrusion. Finally, the punch, which is mounted in a translationally movable manner on the hold-down device, is moved translationally in such a way that the punch loads the contact protrusion via the end face of the contact protrusion. During this process, the contact protrusion is deformed by the punch until the end face of the contact protrusion is flush with the first side of the circuit board. The first side is then populated with the component and the component is connected to the contact protrusion and, if applicable, to the circuit board. In this case, the component lies flat against the end face of the contact protrusion and against the first side of the circuit board. The connection between the component and the contact protrusion, as well as with the circuit board, is made by soldering, in particular by means of a solder paste.

The punch can have a flat or convex acting surface or one having a central projection. With a flat acting surface, the end face of the contact protrusion is subjected to a uniform load. In the case of a convex acting surface or one with a central projection, especially a point, a higher force acts in the center of the end face of the contact protrusion than in the outer areas, as a result of which the material of the contact protrusion is deliberately and uniformly pressed radially outward during upsetting.

A counter-holder can be arranged on the receiving unit, which bears against the busbar on a side facing away from the circuit board in the area of the contact protrusion, wherein the counter-holder is mounted on the receiving unit either fixedly or translationally movable in the longitudinal direction of the contact protrusion and is spring-preloaded. The counter-holder in particular engages in a forming-tool engagement recess of the busbar. By means of the translationally movable, spring-preloaded counter-holder, overloading of the contact protrusion or the busbar during the forming process, i.e., during upsetting, can be reliably avoided, wherein the force acting against the punch can be adjusted by selecting a spring element providing the spring preload and having a defined spring characteristic.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a section of an example of an electrical control unit in cross section; and

FIG. 2 shows a section of an example of an electrical control unit in cross section;

FIG. 3 shows a forming tool for producing an electrical control unit from FIGS. 1 and 2 in cross section;

FIG. 4a shows a section of the forming tool from FIG. 3 in an example in cross section;

FIG. 4b shows a section of the forming tool from FIG. 3 in an example in cross section; and

FIG. 4c shows a section of the forming tool from FIG. 3 in an example in cross section.

### DETAILED DESCRIPTION

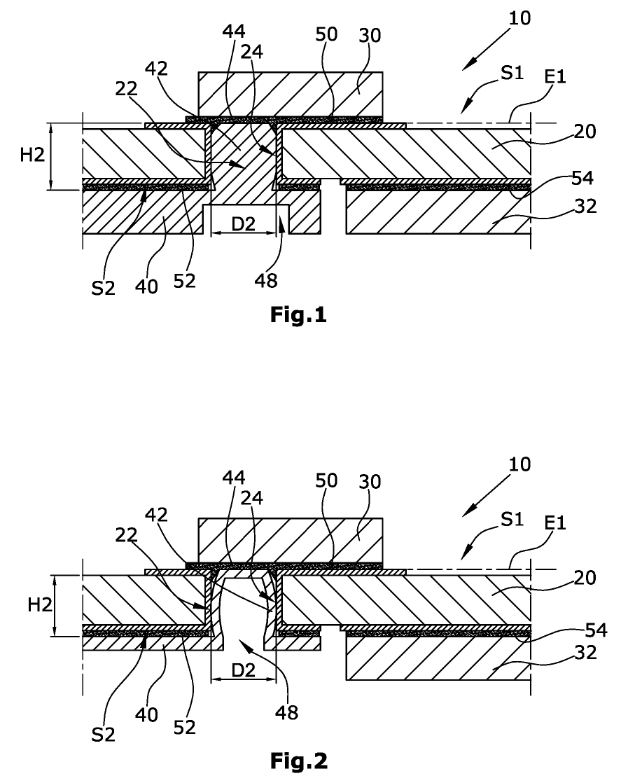

FIGS. 1 and 2 show two examples of an electrical control unit 10, which is used, for example, in vehicles to control an electrically operated vehicle device.

Electrical control unit 10 comprises a circuit board 20, a plurality of components 30, 32, and at least one busbar 40.

The printed circuit board, also known as a PCB, is an electrical circuit whose components and conductors are installed within a mechanical structure. The conductive parts include copper traces, pads, heat sinks, or conductive surfaces. The mechanical structure consists of insulating materials located between layers of conductive material. Circuit board 20 has a plate-like shape such that circuit board 20 comprises a first side S1 and an opposite second side S2.

Components 30, 32 are designed as semiconductor power components, in particular SMD components, wherein SMD components, in contrast to THT components, do not comprise wire connections, but are soldered directly onto circuit board 20 by means of solderable contact surfaces or connecting pins. A first component 30 is arranged on a first side S1 of circuit board 20 and a second component 32 is arranged on a second side S2 of circuit board 20. An electrical control unit 10 typically comprises additional components and additional busbars, wherein a component can also be an electrical connecting element, which, for example, connects two separate busbars together.

Busbar 40 is made like a sheet and is arranged on second side S2 of circuit board 20. Busbar 40 is a single piece and made of an electrically conductive, metallic material.

Busbar 40 is used to contact different components to each other. Busbar 40 shown in FIGS. 1 and 2 is mechanically and electrically connected to circuit board 20 and to component 30. Busbar 40 is connected to first side S1 of circuit board 20 and to first component 30 via a first solder layer 50, and to second side S2 of circuit board 20 via a second solder layer 52. Second component 32 is connected to second side S2 of circuit board 20 via a third solder layer 54.

Busbar 40 has a contact protrusion 42 on the first side of circuit board 20 for contacting first component 30. Circuit board 20 has a through-hole 22 corresponding to the contact protrusion, wherein in an end-assembled state of electrical control unit 10 contact protrusion 42 engages in through-hole 22, such that contact protrusion 42 extends starting from second side S2 of circuit board 20 to first side S1. In order to contact first component 30 with circuit board 20 and contact protrusion 42, end face 44 of contact protrusion 42 is arranged flush with first side S1 of circuit board 20. In other words, end face 44 of contact protrusion 42 is arranged in plane E1 of first side S1 of circuit board 20.

The flush arrangement of end face 44 of contact protrusion 42 with respect to first side S1 of circuit board 20 is realized in such a way that contact protrusion 42 is mechanically formed, i.e., upset, when busbar 40 is already mounted on circuit board 20; i.e., contact protrusion 42 is already inserted into through-hole 22 and busbar 40 is in contact with second side S2 of circuit board 20, wherein the components are not yet soldered together.

The crucial difference between the two embodiments shown in FIGS. 1 and 2 is that contact protrusion 42 in FIG. 2 has a U-shaped longitudinal section and a constant wall thickness, and contact protrusion 42 in FIG. 1 is made as a solid material. In both cases, contact protrusion 40 is upset, whereby the type of deformation differs in the different versions.

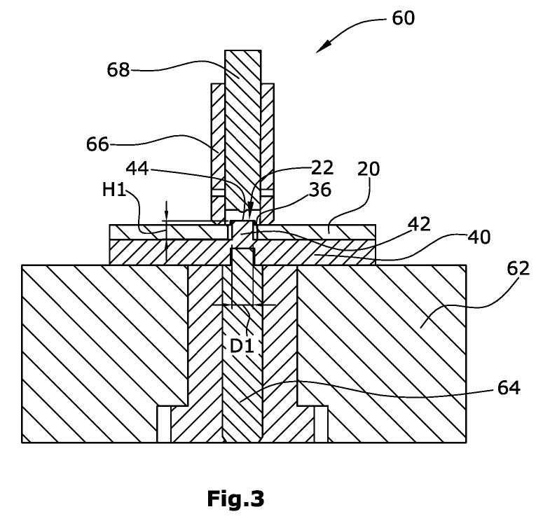

FIG. 3 shows a forming tool 60 by which contact protrusion 42 can be mechanically formed. Forming tool 60 comprises a receiving unit 62, a counter-holder 64 arranged on receiving unit 62, a movable hold-down device 66, and a punch 68 which can be translationally moved on hold-down device 66.

Receiving unit 62 and counter-holder 64 are designed such that during the assembly process or during the forming process, busbar 40 and circuit board 20 are received in such a way that busbar 40 bears against receiving unit 62 and circuit board 20 bears with second side S2 against busbar 40, wherein contact protrusion 42 of busbar 40 protrudes into through-hole 22 of circuit board 20. Counter-holder 64 projects into a forming-tool engagement recess 48 of busbar 40, wherein the counter-holder is mounted on receiving unit 62 either fixedly or translationally movable and is spring-preloaded, i.e., yielding under a predefined force by punch 68. Hold-down device 66 bears against first side S1 of circuit board 20 and is subjected to a holding force in the direction of circuit board 20, whereby circuit board 20 and busbar 40 are clamped between receiving unit 62 and counter-holder 64 and hold-down device 66. As a result, busbar 40 is in contact with the second side of circuit board 20. Punch 68 exerts a forming force on end face 44 of contact protrusion 42 during the forming process.

During the forming process, circuit board 20 and busbar 40 are positioned on receiving unit 62 and on counter-holder 64, such that busbar 40 bears against second side S2 of circuit board 20, and contact protrusion 42 due to the maximum length H1 extends beyond first side S1 of circuit board 20 in the longitudinal direction of contact protrusion 42. Hold-down device 66 is then attached to circuit board 20, for example, by a translational movement, whereby busbar 40 and circuit board 20 are pressed together and thus held together in the longitudinal direction of contact protrusion 42. Finally, punch 68 is repositioned and loaded in such a way that punch 68 loads end face 44 of contact protrusion 42. In this process, contact protrusion 42 is deformed by punch 68 to an end-assembly length H2 until end face 44 of contact protrusion 42 is flush with first side S1 of circuit board 20. By upsetting contact protrusion 42, the original outer diameter D1 of contact protrusion 42 increases to an end-assembly outer diameter D2, wherein contact protrusion 42 in the original state is spaced apart, at least in sections, from inner circumferential surface 24 of through-hole 22 when viewed in the circumferential direction and in the end-assembled state bears against the inner circumferential surface 24 of through-hole 22 transversely to the longitudinal direction of contact protrusion 42. In this process, contact protrusion 42 is shortened during upsetting, which presses the material of contact protrusion 42 radially outward, thereby increasing the diameter of the contact protrusion. In particular, the upsetting of contact protrusion 42 causes a curved or bulging circumferential surface of contact protrusion 42, wherein the end-assembly outer diameter D2 of contact protrusion 42 is largest in the center in the longitudinal direction and decreases from the center to the edge.

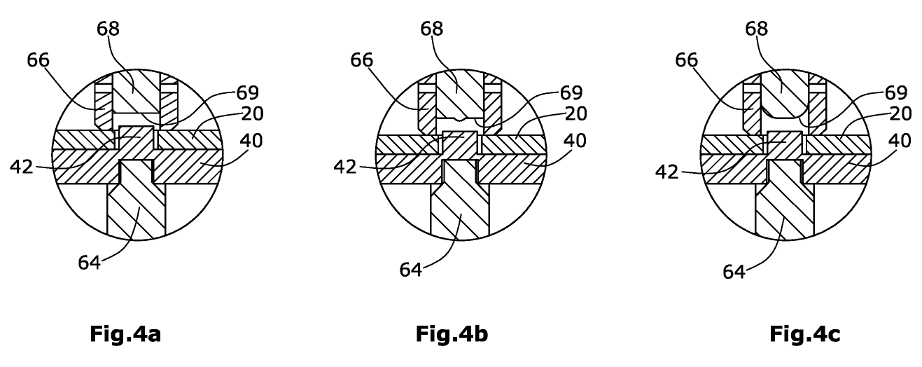

In order to deliberately cause such forming of contact protrusion 42, punch 68 has an acting surface 69 that is convex according to FIG. 4c or has a pointed projection in the center according to FIG. 4b. Alternatively, punch 68 can have a flat acting surface 69, as shown in FIG. 4a, wherein, in the case of a flat acting surface 69, the end face of contact protrusion 42 is subjected to a uniform load. In the case of a convex acting surface 69 or one having a central projection, especially a point, a higher force acts radially in the center of end face 44 of contact protrusion 42 than in the outer areas, as a result of which the material of contact protrusion 42 is deliberately and uniformly pressed radially outward during upsetting.

After forming the contact protrusion, forming tool 60 is removed and first side S1 is populated with first component 30 and component 30 is connected to contact protrusion 42 and to circuit board 20. In this case, component 30 lies flat against end face 44 of contact protrusion 42 and against circuit board 20 on first side S1, which is arranged flush with end face 44. The connection between component 30 and contact protrusion 42 as well as with circuit board 20 is made by soldering. Second component 32 is soldered to second side S2 of circuit board 20.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An electrical control unit comprising:
a circuit board;
a component arranged on a first side of the circuit board; and
a busbar arranged on a second side of the circuit board, the busbar comprising a contact protrusion and the circuit board has a through-hole corresponding to the contact protrusion, the contact protrusion extending into the through-hole of the circuit board such that an end face of the contact protrusion is arranged flush with the first side of the circuit board in the longitudinal direction of the contact protrusion and is electrically contacted with the component,
wherein the contact protrusion in an original state has a predefined maximum length and is mechanically formed to an end-assembly length in the end-assembled state.

2. The electrical control unit according to claim 1, wherein the contact protrusion is mechanically upset such that the busbar bears against the second side of the circuit board and the end face of the contact protrusion is arranged flush with the first side of the circuit board.

3. The electrical control unit according to claim 2, wherein the contact protrusion is upset such that the end-assembly outer diameter of the contact protrusion is, at least in sections, greater than the original outer diameter, wherein the contact protrusion in the original state is spaced apart, at least in sections, from an inner circumferential surface of the through-hole, when viewed in the circumferential direction, and wherein, in the end-assembled state, the contact protrusion is supported on the circuit board transversely to the longitudinal direction of the contact protrusion by abutment against the inner circumferential surface of the through-hole.

4. The electrical control unit according to claim 1, wherein the contact protrusion has a U-shaped longitudinal section.

5. The electrical control unit according to claim 1, wherein the contact protrusion is made as a solid material.

6. The electrical control unit according to claim 1, wherein the busbar has a forming-tool engagement recess on a side facing away from the contact protrusion.

7. The electrical control unit according to claim 1, wherein the busbar has at least two contact protrusions.

8. The electrical control unit according to claim 1, wherein the component is a power semiconductor component or an electrical connecting element.

9. A manufacturing process for producing the electrical control unit according to claim 1, the process comprising:
providing a circuit board;
providing a component;
providing a busbar;
mounting the busbar on the circuit board;
inserting the contact protrusion into the through-hole of the circuit board and is mechanically formed from the maximum length to the end-assembly length such that an end face of the contact protrusion is arranged flush with a first side of the circuit board and such that the busbar bears against a second side of the circuit board;
populating the first side of the circuit board with the component such that the component bears at least against the end face of the contact protrusion; and
connecting the component at least to the contact protrusion.

10. The manufacturing process according to claim 9, wherein the component is soldered to the contact protrusion.

11. The manufacturing process according to claim 9, wherein the component is connected to the first side of the circuit board and to the busbar.

12. A forming tool for manufacturing an electrical control unit according to claim 1, the forming tool comprising:
a receiving unit designed to receive a busbar and a circuit board, wherein during the forming process the busbar bears against the receiving unit and the circuit board bears with a second side against the busbar such that a contact protrusion of the busbar is arranged in a through-hole of the circuit board;
a hold-down device which bears against a first side of the circuit board during the forming process; and
a punch, which is translationally movable, such that during the forming process the punch acts on the end face of the contact protrusion.

13. The forming tool according to claim 12, wherein the punch has a flat or convex acting surface or one with a central projection.

14. The forming tool according to claim 12, wherein the punch is mounted in a translationally movable manner on the hold-down device.

15. The forming tool according to claim 12, wherein a counter-holder is arranged on the receiving unit, which bears against the busbar on a side facing away from the circuit board in an area of the contact protrusion, and wherein the counter-holder is mounted on the receiving unit either fixedly or translationally movable in the longitudinal direction of the contact protrusion and is spring-preloaded.
